(19) United States
(12) Patent Application Publication
(10) Pub. No.: US 2008/0042255 A1
(43) Pub. Date: Feb. 21, 2008

(54) CHIP PACKAGE STRUCTURE AND FABRICATION METHOD THEREOF

(75) Inventor: CHIN-TI CHEN, HSINCHU (TW)

Correspondence Address: ROSENBERG, KLEIN & LEE, 3458 ELLICOTT CENTER DRIVE-SUITE 101, ELLICOTT CITY, MD, 21043, US

(73) Assignee: POWERTECH TECHNOLOGY INC., HSINCHU (TW)

(21) Appl. No.: 11/757,601

(22) Filed: Jun. 4, 2007

(30) Foreign Application Priority Data
Aug. 15, 2006 (TW) 95129962

(51) Int. Cl. H01L 23/04; H01L 21/02

(52) U.S. Cl. 257/698; 438/118; 257/E23.067; 257/E21.52

(57) ABSTRACT

A chip package structure and a fabrication method thereof are disclosed herein. The fabrication method includes: providing a substrate, wherein at least a through hole penetrates through the substrate; forming a block element surrounding the through hole of the substrate; forming an adhesive element surrounding the block element; disposing a chip on the substrate to cover the through hole, wherein the chip is fixed on the substrate with the adhesive element, wherein an active surface of the chip faces toward to the through hole and a portion of the active surface exposes to the through hole; electrically connecting the active surface of the chip to the lower surface of the substrate with a electrically-connecting element; and forming an encapsulant covering the abovementioned elements. Wherein the block element arranged around the through hole can avoid the overflow of the adhesive element, which may pollute those electrical contacts of the active surface of the chip, and restrict the stature of the adhesive element so as to reduce the probability of the particle pollution issue (for example the EMC filler), which may damage the active surface of the chip.

### BACKGROUND OF THE INVENTION

1. Field of the Invention

The present invention relates to a chip package structure and fabrication method thereof, and more particularly, to a window chip package structure and a fabrication method thereof for preventing the package from paste bleeding.

2. Description of the Prior Art

Along with the rapid progress of semiconductor industry, the semiconductor products need to be multi-functional, portable, light, thin, and small-sized to satisfy the customers' demand. Therefore, there are many challenges of the package manufacturing process needed to be overcomed, such as the more complicated design of the lead frame, the choice of the package material, the warpage issue of the thin-type package, thermal issue, structure strength, and so on.

A conventional window-type BGA(ball grid array) structure is shown in FIG. 1A. As shown in the figure, a circuit board 100 having a window on it is fixed with a chip 400, and a plurality of metal wires 500 penetrating through the window to electrically connect the circuit board 100 to the chip 400. In addition, a plurality of array-arranged solder balls 700 set on the circuit board 100. However, when die attaching process is proceeded, the die-attach paste 300 is easily to bleed to pollute the bonding position 402 of the chip 400 or the circuit board 100. Furthermore, such as shown in FIG. 1B, if the die-attach paste 300 is coated insufficiently, the chip 400 not only could not be tightly fixed on the circuit board 100 but also could crack causing from the mold flow in the molding process.

### SUMMARY OF THE INVENTION

According to the issue mentioned previously, the present invention is to provide a chip package structure and a fabrication method thereof. It utilizes the block element set around the window of the circuit board to control the amount and the thickness of the die-attach paste, and by using the method of limiting the stature of the die-attach paste, it can reduce the probability of the particle, such as epoxy molding compound filler (EMC filler), invading to damage the active surface of the chip.

For solving the paste bleeding problem which may pollute the solder pads on the chip, one object of the present invention is to provide a chip package structure and a fabrication method thereof which utilizes the block elements arranged around the opening of the circuit board to prevent the solder pads on the chip or other circuits on the circuit board from being polluted by the die-attach paste pressed to bleed.

One object of the present invention is to provide a chip package structure and a fabrication method thereof which utilizes the block elements to prevent the solder pads on the chip or other circuits on the circuit board from being polluted by the die-attach paste so as to improve the fabrication yield and reduce the manufacturing cost.

One object of the present invention is to provide a chip package structure and a fabrication method thereof which utilizes the block element arranged on the circuit board to provide a support to the chip so as to prevent the chip from damaging by the molding compound.

To achieve the objects mentioned above, one embodiment of the present invention is to provide a chip package strucutre, including: a substrate; at least a through hole penetrating through the substrate; a block element set on an upper surface of the substrate and surrounding the through hole of the substrate; an adhesive element surrounding the block element; a chip set on the upper surface of the substrate to cover the through hole and attached on the substrate with the adhesive element, wherein an active surface of the chip faces toward to the through hole; an electrical-connecting element piercing through the through hole of the substrate and electrically connecting the active surface of the chip to a lower surface of the substrate; and an encapsulant covering the chip, the adhesive element, the block element, and the electrical-connecting element.

To achieve the objects mentioned above, another embodiment of the present invention is to provide fabrication method of a chip package structure, including: providing a substrate which has at least a through hole penetrating through the substrate; forming a block element on the substrate and surrounding the through hole; forming an adhesive element surrounding the block element; disposing a chip on the substrate to cover the through hole, wherein the chip is attached on the substrate with the adhesive element, wherein an active surface of the chip faces toward to the through hole and a portion of the active surface exposes to the through hole; electrically connecting the active surface of the chip to a lower surface of the substrate with an electrical-connecting element; and forming an encapsulant covering the chip, the adhesive element, the block element, and the electrical-connecting element.

Other objects, technical contents, features and advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A is the cross-sectional schematic diagram to illustrate the conventional window BGA structure;

FIG. 1B is the cross-sectional schematic diagram to illustrate the conventional window BGA structure;

FIG. 2A, FIG. 2B, FIG. 2C, FIG. 2D, FIG. 2E, FIG. 2F, and FIG. 2G-1 are the cross-sectional schematic diagrams to illustrate the process steps of the chip package structure according to one embodiment of the present invention;

FIG. 2G-2 is the partially enlarged schematic diagram of FIG. 2G-1 of the present invention; and

FIG. 3 is the cross-sectional schematic diagram to illustrate the chip package structure according to another one embodiment of the present invention.

### DESCRIPTION OF THE PREFERRED EMBODIMENT

The detailed explanation of the present invention is described as following. The described preferred embodiments are presented for purposes of illustrations and description, and they are not intended to limit the scope of the present invention.

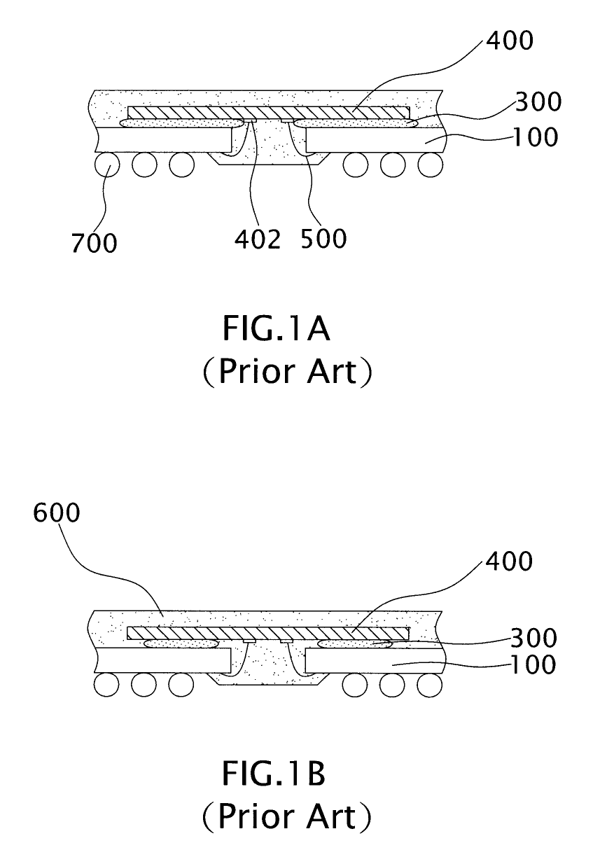

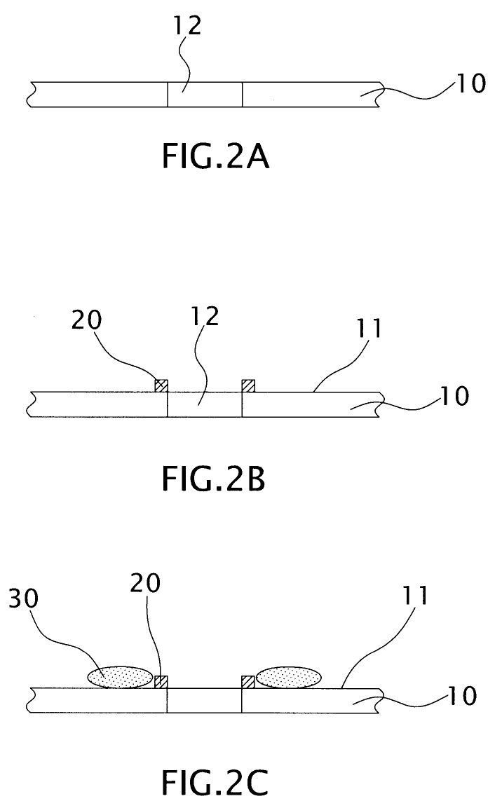

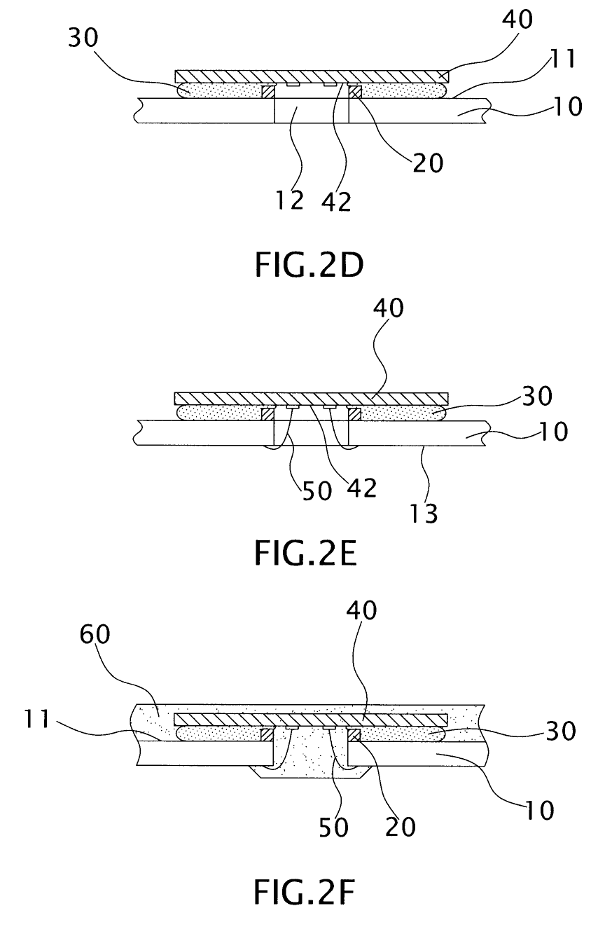

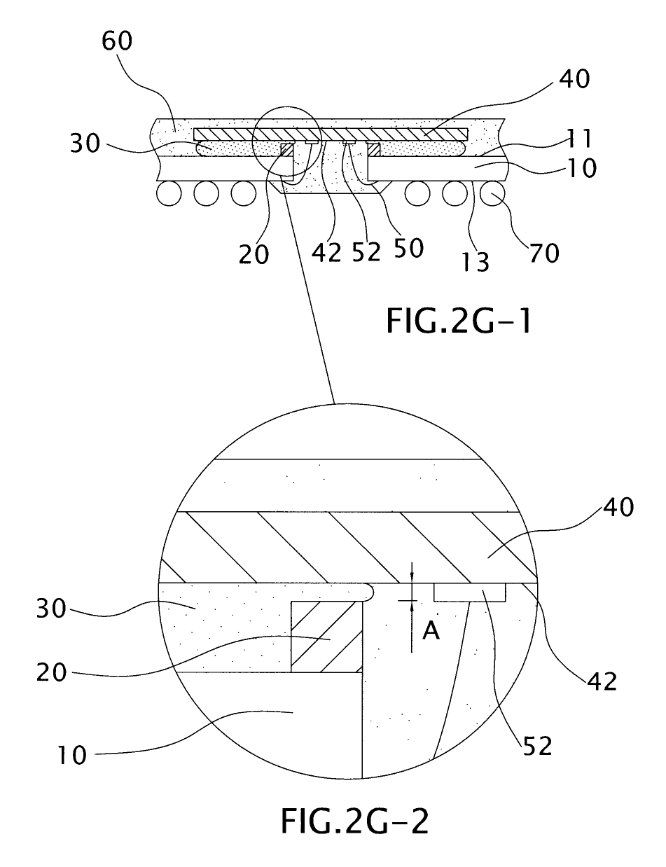

FIG. 2A, FIG. 2B, FIG. 2C, FIG. 2D, FIG. 2E, FIG. 2F, and FIG. 2G-1 are the cross-sectional schematic diagrams to illustrate the process steps of the chip package structure according to one embodiment of the present invention. Firstly, refer to FIG. 2A, a substrate 10, which is made of metal, glass, ceramics or polymer, is provided with at least a through hole 12 penetrating through the substrate 10, wherein the substrate 10 can be the one whose through hole 12 is formed by an appropriate method, or the commercialized product provided with at least a through hole 12.

Next, refer to FIG. 2B, a block element 20 is set around the through hole 12 on an upper surface 11 of the substrate 10. In one embodiment, the block element 20 is formed by utilizing any one of sputtering method, evaporation method, electroless-plating method, and electroplating method or any one of screen printing method, curtain coating method, spray coating method, roller coating method, electrostatic spraying method, and ink-jet printing method. In addition, the stature of the block element 20 can be designed according to the stature of the package.

Next, as shown in FIG. 2C, an adhesive element 30, such as a sliver paste or a B-stage paste, is attached on the substrate 10 and surrounding the block element 20. In one embodiment, the adhesive element 30 is formed by utilizing any one of the stamping method, the screen printing method, and the syringe transfer method, and the thinkness of the adhesive element 30 can be restricted with the stature of the block element 20 so as to control the amount of the adhesive element 30.

Next, refer to FIG. 2D, as shown in the figure, this process proceeds to a chip-attachment procedure. A chip 40 is set on the upper surface 11 of the substrate 10 and covers the through hole 12 of the substrate 10. In addition, the chip 40 is attached on the substrate 10 with the adhesive element 30, wherein an active surface 42 of the chip 40 faces toward to the through hole 12 and a portion of the active surface 42 exposes to the through hole 12. Next, the wire bonding method is utilized to electrically connect the exposed active surface 42 of the chip 40 to the lower surface 13 of the substrate 10, as shown in FIG. 2E. In the embodiment, an electrical-connecting element is utilized to electrically connect the chip 40 with the substrate 10, wherein the electrical-connecting element can include at least a wire 50, at least a connecting pad, or its combination. Finally, refer to FIG. 2F, an encapsulent 60 is formed by such as molding method to cover the chip 40, the adhesive element 30, the block element 20, and the electrical-connecting element. In one embodiment, the process further includes disposing a plurality of solder balls 70 on the lower surface 13 of the substrate 10 to electrically connect to an external device, such as shown in FIG. 2G-1.

Continuing the above description, refer to FIG. 2G-1, in the meantime, the chip structure includes a substrate 10, which is made of metal, glass, ceramics or polymer. At least a through hole penetrates through the substrate 10 by utilizing an appropriate method. A block element 20 is set on an upper surface 11 of the substrate 10 and surrounds the through hole. In one embodiment, the block element 20, which is formed by an appropriate method, can be a metal layer, a non-conductive layer (such as plastics), or a solder mask, wherein the material of the metal layer includes gold(Au) or other metal whose coefficient of the thermal expansion(CTE) is similar to the CTE of the encapsulant 60. An adhesive element 30 is set to surround the block element 20 by an appropriate method, wherein the adhesive element 30 can be the silver paste or the B-stage paste. A chip 40 is set on the upper surface 11 of the substrate 10 to cover the through hole, and is attached on the substrate 10 by the adhesive element 30, wherein an active surface 42 of the chip 40 faces toward to the through hole. An electrical-connecting element, such as composed of at least a wire 50, at least a connecting pad, or its combination, pierces through the through hole of the substrate 10 and electrically connecting to a lower surface 13 of the substrate 10. And, an encapsulant 60 covers the chip 40, the adhesive element 30, the block element 20, and the electrical-connecting element.

In one embodiment, refer to FIG. 2G-2, FIG. 2G-2 is the partially enlarged schematic diagram of FIG. 2G-1 of the present invention. As shown in the figure, there is a gap A between the chip 40 and the block element 20, and the gap A is at least partially filled with the adhesive element 30. When the chip 40 is attached on the substrate 10, the adhesive element 30 is pressed to flow along the gap A which is between the block element 20 and the chip 40 to partially cover the block element 20. Owing to the block element 20, the pressed adhesive element 30 would just bleed to the gap A instead of polluting the connecting pad 52 on the active surface 42 of the chip 40. Furthermore, the block element 20 can be utilized to control the stature of the adhesive element 30 to reduce the probability of the invading particle, which is from the adhesive element 30 or the encapsulant 60, to damage the active surface of the chip.

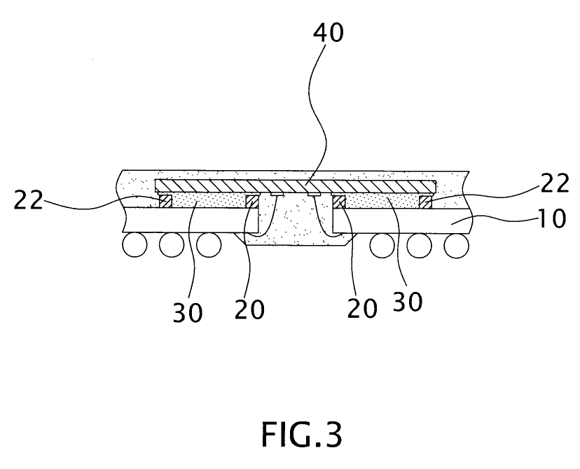

Referring to FIG. 3, FIG. 3 is the cross-sectional schematic diagram to illustrate the chip package structure according to another embodiment of the present invention. The difference between last embodiment and this one is the position of the block element 22. In this embodiment, the block element 22 can further be set around the adhesive element 30 to prevent other circuit of the substrate 10 or other electronic components from damaging by the adhesive element 30. Moreover, the stature of the block element 20, 22 can be utilized to control the coating amount and the thickness of the adhesive element 30. Besides, when the molding process is proceed, the crack problem of the chip 40 can be improved due to the support of the block element 20, 22. The shape of the block element 20, 22 is not limited. In other words, any component provided with the blocking effect surrounding the through hole are included in the spirit of the present invention.

According to the above description, one feature of the present invention is to utilize the block element set on the substrate to define the coating region of the adhesive element so as to control the paste amount and provide a support to the chip. Additionally, the shape and the amount of the block element are not limited. In other words, as long as the block element sets around the through hole and protrudes from the substrate without changing the thickness of the whole package structure, the shape and the amount can be various.

To summarize, the present invention utilizes the block element surrounding the through hole of the substrate to control the amount and the thickness of the die-attach paste, and by using the method of limiting the stature of the die-attach paste, it can reduce the probability of the particle, such as epoxy molding compound filler (EMC filler), invading to damage the active surface of the chip. Further, for solving the paste bleeding problem which may pollute the solder pads on the chip, present invention utilizes the block elements surrounding the through hole of the substrate to prevent the solder pads on the chip or other circuits on the substrate from being polluted by the die-attach paste pressed to bleed. In addition, the block element is utilized to prevent the solder pads on the chip or other circuits on the substrate from being polluted by the die-attach paste so as to improve the fabrication yield and reduce the manufacturing cost. Furthermore, the block element is utilized to provide a support to the chip so as to prevent the chip from damaging by the molding compound.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. A chip package strucutre, comprising:
a substrate;
at least a through hole penetrating through said substrate;
a block element set on an upper surface of said substrate and surrounding said through hole of said substrate;
an adhesive element surrounding said block element;
a chip set on said upper surface to cover said through hole and fixed on said substrate with said adhesive element, wherein an active surface of said chip faces toward to said through hole;
an electrical-connecting element piercing through said through hole of said substrate and electrically connecting said active surface of said chip with a lower surface of said substrate; and
an encapsulant covering said chip, said adhesive element, said block element, and said electrical-connecting element.

2. The chip package strucutre according to claim 1, wherein a gap is formed between said chip and said block element, and said gap is at least partially filled with said adhesive element.

3. The chip package strucutre according to claim 1, wherein said block element is further set around said adhesive element.

4. The chip package strucutre according to claim 1, wherein said block element is a metal layer.

5. The chip package strucutre according to claim 4, wherein said metal layer is made of gold(Au).

6. The chip package strucutre according to claim 1, wherein said block element is a solder mask.

7. The chip package strucutre according to claim 1, wherein said block element is a non-conductive layer.

8. The chip package strucutre according to claim 1, wherein said adhesive element is any one of a silver paste and a B-stage paste.

9. The chip package strucutre according to claim 1, further comprising a plurality of solder balls set on said lower surface of said substrate.

10. The chip package strucutre according to claim 1, wherein said electrical-connecting element comprises at least a wire or at least a connecting pad.

11. A chip package structure fabrication method, comprising:
providing a substrate which has at least a through hole penetrating through said substrate;
forming a block element on said substrate and surrounding said through hole;
forming an adhesive element surrounding said block element;
disposing a chip on said substrate to cover said through hole, and said chip attached on said substrate by said adhesive element, wherein an active surface of said chip faces toward to said through hole and a portion of said active surface exposes to said through hole;
electrically connecting said active surface of said chip to a lower surface of said substrate with an electrical-connecting element; and
forming an encapsulant covering said chip, said adhesive element, said block element, and said electrical-connecting element.

12. The chip package structure fabrication method according to claim 11, wherein said block element is formed by utilizing any one of sputtering method, evaporation method, electroless-plating method, and electroplating method.

13. The chip package structure fabrication method according to claim 11, wherein said block element is formed by utilizing any one of screen printing method, curtain coating method, spray coating method, roller coating method, electrostatic spraying method, and ink-jet printing method.

14. The chip package structure fabrication method according to claim 11, wherein the method of electrically connecting said chip with said substrate is a wire bonding method.

15. The chip package structure fabrication method according to claim 11, further comprising disposing a plurality of solder balls on said lower surface of said substrate.
